(19) United States
(12) Patent Application Publication
(10) Pub. No.: US 2002/0037604 A1
(43) Pub. Date: Mar. 28, 2002

(54) Lead frame, semiconductor package having lead frame, and method of manufacturing semiconductor package

(76) Inventors: Sang-kyun Lee, Yongin-city (KR); Bong-hui Lee, Yongin-city (KR)

Correspondence Address: Finnegan, Henderson, Farabow,, Garrett & Dunner, L.L.P., 1300 I Street, N.W., Washington, DC, 20005-3315, US

(21) Appl. No.: 09/953,195

(22) Filed: Sep. 17, 2001

(30) Foreign Application Priority Data
Sep. 15, 2000 (KR) 2000-54200
Jul. 13, 2001 (KR) 2001-42344

(51) Int. Cl. H01L 23/495; H01L 21/44; H01L 21/48

(52) U.S. Cl. 438/112; 257/670

(57) ABSTRACT

A lead frame for a semiconductor package includes a pad, a support portion where a plurality of leads are formed, and a tie bar for supporting the pad, in which one end of the tie bar is connected to the support portion and the other end thereof is connected to the pad, wherein the height from the support portion to the pad when the tie bar is down-set processed is greater than the height from the support portion to the pad when an encapsulation is formed.

### BACKGROUND OF THE INVENTION

1. Field of the Invention

The present invention relates to a lead frame, a semiconductor package having the lead frame, and a method for manufacturing the semiconductor package, and more particularly, to a lead frame in which a flash phenomenon occurring to molding resin in a semiconductor package can be prevented, a semiconductor package having the lead frame, and a method for manufacturing the semiconductor package.

2. Description of the Related Art

In general, a semiconductor package is formed by arranging a semiconductor chip on a pad of a lead frame, wire-bonding an electrode of the semiconductor chip and an inner lead of the lead frame, and encapsulating the pad and the inner lead frame with molding resin.

Recently, the capacity of a semiconductor package becomes large while the size thereof is reduced. For example, a chip scale package (CSP) is developed. While leads protrude from the side surface of a semiconductor package in the conventional semiconductor package, in the chip scale package, leads protrude from the bottom surface of the semiconductor package. If the leads protrude from the bottom surface of the semiconductor package, the size of the package drastically decreases and a space occupied by the package is further reduced. To expose leads to the bottom surface of the package, the leads need to circuit board. In some particular cases, a pad on which a semiconductor chip is arranged is exposed to the bottom surface of the package.

FIG. 1 is a sectional view of a semiconductor package according to a conventional technology, which is disclosed in Japanese Patent Publication No. 59-21047. Referring to the drawing, a semiconductor chip 14 is mounted on the upper a surface of a pad 11 and a lead 12 is down-set processed. A bottom surface 12a of the lead 12 is exposed to the bottom surface of an encapsulation 15 so that the lead 12 can contact a connection terminal (not shown) on a printed circuit board. An upper end of the lead 12 and an electrode (not shown) of the semiconductor chip 14 are connected by a bonding wire 13. The pad 11 is positioned lower than the upper end of the lead 12. The semiconductor package of FIG. 1 is a typical example in which the lead 12 is down-set processed.

FIG. 2 shows another example of a semiconductor package according to the conventional technology, which is disclosed in Japanese Patent Publication No. 59-227143. Referring to the drawing, a semiconductor chip 24 is mounted on a pad 21. A lead 22 is processed by a half-etching method so that a bottom surface 22a thereof is exposed to the bottom surface of an encapsulation 25. One end of the lead 22 and an electrode of the semiconductor chip 24 are connected by a bonding wire 23. The semiconductor package of FIG. 2 is an example in which lead 22 is half-etched.

FIG. 3 shows yet another example of a semiconductor package according to a conventional technology, which is disclosed in U.S. Pat. No. upper surface of a pad 31. A bottom surface of the pad 31 and a bottom surface 32a of a lead 32 are exposed from the bottom surface of an encapsulation 35. That is, the pad 31 and the lead 32 are formed at the same height. The lead 32 and electrodes of the semiconductor chip 34 are connected by a bonding wire 33. The exposed lead 32 contacts a connection terminal on a printed circuit board. The bottom surface of the exposed pad 31 radiates heat generated by the semiconductor chip 34 to the outside. The exposed pad 31 is connected to a thermal pad (not shown) on the printed circuit board. The semiconductor package of FIG. 3 is an example in which the pad 31 is exposed to the outside.

When a semiconductor package described with reference to FIG. 3 is to be manufactured, there are typically two conventional manufacturing methods that can be applied. In the first method, there is a lead frame unit including a separate lead frame 41 and a rail 42 encompassing the lead frame 41 from the outside, as shown in FIG. 4. The lead frame unit undergoes wafer sawing, die attach, wire bonding, molding/deflashing, marking, and trimming/forming. The merit of using a lead frame to which trimming is applied individually is that generation of flash to mold is relatively restricted. However, complete prevention of the flash generation is not possible so that an additional step of removing the flash is actually needed.

In the second method, a lead frame is not individually trimmed, but a lead frame unit in which a plurality of lead frames are arranged in form of matrix is molded together. The lead frame unit in form of matrix is shown in FIG. 5. Here, denotes a rail encompassing each lead frame from the outside. The matrix type lead frame unit is assembled by steps of wafer sawing, die attach, wire bonding, molding/deflashing, marking, and singulation by sawing.

In the above-described two semiconductor package assembly processes, the individually trimmed lead frame has smaller unit density per unit area because the unit area on a lead frame strip is greater than the unit area of the matrix type. Thus, a unit price per unit area increases. To reduce the disadvantage, the matrix type lead frame is more frequently used. However, when a semiconductor package where a pad is exposed to the bottom surface of the package is molded in a matrix form, mold flash can be generated in a molding step such that application of a matrix type lead frame is not possible.

FIG. 6 shows a molding step of a semiconductor package which corresponds to a molding step using a matrix type lead frame. Referring to the drawing, molding of a semiconductor package is formed in a molding plate including an upper plate 61 and a lower plate 62. A space, in which a lead frame connected to a chip by wire bonding is placed, is formed between the upper and lower plates 61 and 62. The space will be filled with molding resin 64. The molding resin 64 may be injected into the space through a gate 63. The lead frame is provided with a pad 65 and a lead 67 and a semiconductor chip 66 is mounted on the upper surface of the pad 65. An electrode of the semiconductor chip 66 and the lead 67 are connected by a bonding wire 68. The lead frame is of a matrix type shown in FIG. 5, which has not cut yet into individual lead frames.

When an encapsulation step is actually performed by using the molding plate shown in FIG. 6, mold flash is generated between the bottom surfaces of the pad 65 and the lead 67 and the inner surface of the lower plate 62. This is because the lead frame is twisted due to thermal expansion as temperature increases in the state in which the lead frame unit is accommodated inside the molding plate. Also, since the upper plate 61 clamps only the edge of the lead frame unit, the central portion except for the edge portion is not clamped so that the lead frame unit is lifted and molding resin intrudes under the lead or the pad, generating flash.

To prevent a flash phenomenon during molding, a method using a rear side tape is introduced. That is, a heat-resistant tape such as polyimide or Teflon is laminated on the rear side of the lead frame. Since an adhesive layer is present on the polyimide tape, the polyimide tape is attached to the inner surface of the lower plate so that generation of flash can be prevented. However, since the method using the rear side tape uses a special tape of a particular company, cost is high and an additional step is needed, increasing an investment cost. Also, after the tape is removed, the adhesive remains on the surface of the lead frame so that a degree of welding is lowered. To remove the adhesive, a chemical process is required.

### SUMMARY OF THE INVENTION

To solve the above-described problems, it is an object of the present

It is another objective of the present invention to provide an improved semiconductor package in which a flash phenomenon and a boundary surface separation phenomenon are prevented.

It is yet another objective of the present invention to provide an improved semiconductor package manufacturing method by which the flash phenomenon and the boundary surface separation phenomenon are prevented.

It is another objective of the present invention to provide a semiconductor package which is assembled by an assembly step which is the same as or similar to the conventional semiconductor package assembly step, a lead frame needed therefore, and an improved manufacturing method.

To achieve the above objectives, there is provided a lead frame for an encapsulated semiconductor package having a predetermined thickness, comprising a pad for receiving a semiconductor chip, the pad having a top surface, a support portion having a bottom surface and a plurality of leads formed on the support portion, a resilient tie bar having a first end connected to the pad and a second end connected to the support portion, the tie bar when in an unstressed condition supporting the pad such that the top surface of the pad and the bottom surface of the supporting portion and leads are separated by a distance greater than the predetermined thickness.

It is preferred that the tie bar is down-set processed.

It is preferred that at least a portion of the plurality of leads is half-etched.

It is preferred that the half-etched portion is electrically connected to the semiconductor chip.

It is preferred that the lead frame when in a stressed condition is configured to fit into a space defined by a pair of molding plates separated by a distance of the predetermined thickness.

To achieve the above objectives, there is provided an encapsulated semiconductor package having a predetermined thickness, comprising a pad having a first surface and a second surface opposite to the first surface, a support portion having a bottom surface and a plurality of leads formed on the support portion, a semiconductor chip attached to the first surface of the pad, a resilient tie bar having a first end connected to the pad and a second end connected to the support portion, and an encapsulation having a first surface and a second surface opposite to the first surface, the second surface of the pad being exposed to the first surface of the encapsulation and the leads being exposed to the second surface of the encapsulation.

It is preferred that the second surface of the pad and the bottom surface of the support portion are separated by a predetermined distance.

It is preferred that the predetermined distance prior to forming the encapsulation is greater than the predetermined thickness.

It is preferred that the encapsulated semiconductor package comprises at least one bonding wire connected between an electrode of the semiconductor chip and each of the plurality of leads.

It is preferred that the resilient tie bar is down-set processed.

It is preferred that the pad and the support portion when in a stressed condition are configured to fit into a space defined by a pair of molding plates separated by a distance of the predetermined thickness.

It is preferred that the first surface of the pad is the bottom surface of the pad and the second surface of the pad is the upper surface of the pad, and that the first surface of the encapsulation is the upper surface of the encapsulation and the second surface of the encapsulation is the bottom surface of the encapsulation.

It is preferred that the first surface of the pad is the upper surface of the pad and the second surface of the pad is the bottom surface of the pad, and that the first surface of the encapsulation is the bottom surface of the encapsulation and the second surface of the encapsulation is the upper surface of the encapsulation.

It is preferred that at least a portion of the plurality of leads is half-etched.

It is preferred that the half-etched portion is electrically connected to the semiconductor chip.

To achieve the above objectives, there is provided a method of manufacturing a semiconductor package, comprising providing a lead frame comprising a pad, a plurality of leads, and a tie bar extending from the pad and supporting the pad, down-set processing the tie bar so that the pad and the leads are disposed on different axial planes with a predetermined distance from each other, deforming the lead frame by providing a pair of molding plates on opposite sides of the lead frame and separated from each other by a predetermined thickness for forming an encapsulation, the predetermined thickness being less than a sum of the predetermined distance, a thickness of the pad, a thickness of the lead, and injecting a molding resin between the molding plates to form an encapsulated package.

It is preferred that the method comprises a step of half-etching at least a portion of the leads.

It is preferred that the method comprises a step of electrically connecting the half-etched portion to a semiconductor chip.

It is preferred that the method comprises attaching a semiconductor chip to one surface of the pad.

It is preferred that the method comprises connecting an electrode of the semiconductor chip and the leads by a bonding wire.

It is preferred that the method comprises accommodating the lead frame in the inside space between the pair of molding plates, pressing the pad which makes a contact with a surface of one of the molding plates, and injecting the molding resin into the inside space while pressing the pad, thus forming the encapsulation.

It is preferred that the method comprises cutting a portion connecting to the leads.

It is preferred that the semiconductor chip is attached to a bottom surface of the pad.

It is preferred that the semiconductor chip is attached to the upper surface of the pad.

It is preferred that the lead frame is provided as a lead frame unit where a plurality of lead frames are connected in a matrix format.

It is preferred that the lead frame is an individually molded and trimmed lead frame.

It is preferred that the plurality of leads are formed on a support portion, the support portion connected to the tie bar for providing a support for the pad.

It is to be understood that both the foregoing general description and the following detailed description are exemplary and explanatory only and are not restrictive of the invention, as claimed.

### BRIEF DESCRIPTION OF THE DRAWINGS

The above objectives and advantages of the present invention will become more apparent by describing in detail preferred embodiments thereof with reference to the attached drawings in which:

FIG. 1 is a sectional view showing a conventional semiconductor package;

FIG. 2 is a sectional view showing another conventional semiconductor package;

FIG. 3 is a sectional view showing yet another conventional semiconductor package;

FIG. 4 is a plan view showing a strip of a lead frame unit which is individually trimmed after being resin molded;

FIG. 5 is a plan view showing a strip of a matrix type lead frame unit;

FIG. 6 is a sectional view showing a method of molding a semiconductor package according to a conventional technology, in which a matrix type lead frame unit is applied;

FIG. 7 is a sectional view showing a semiconductor package according to an embodiment consistent with the present invention;

FIG. 8 is a perspective view showing a lead frame used for forming the semiconductor package of FIG. 7;

FIG. 9 is a plan view showing the lead frame of FIG. 8;

FIGS. 10A through 10E are views showing a method of manufacturing a semiconductor package consistent with the present invention;

FIG. 11 is a bottom view of a completed semiconductor package;

FIGS. 12A and 12B are sectional views for explaining a state in which the lead frame is pressed by the molding plate;

FIG. 13 is a sectional view for explaining a molding step in which a matrix type lead frame unit on which the semiconductor chip is mounted is accommodated in the molding plate;

FIGS. 14A and 14B are sectional views for explaining a method of manufacturing a semiconductor package according to another embodiment consistent with the present invention; and

FIG. 15 is an exploded perspective view showing a method of manufacturing the semiconductor package described with reference to FIGS. 14A and 14B.

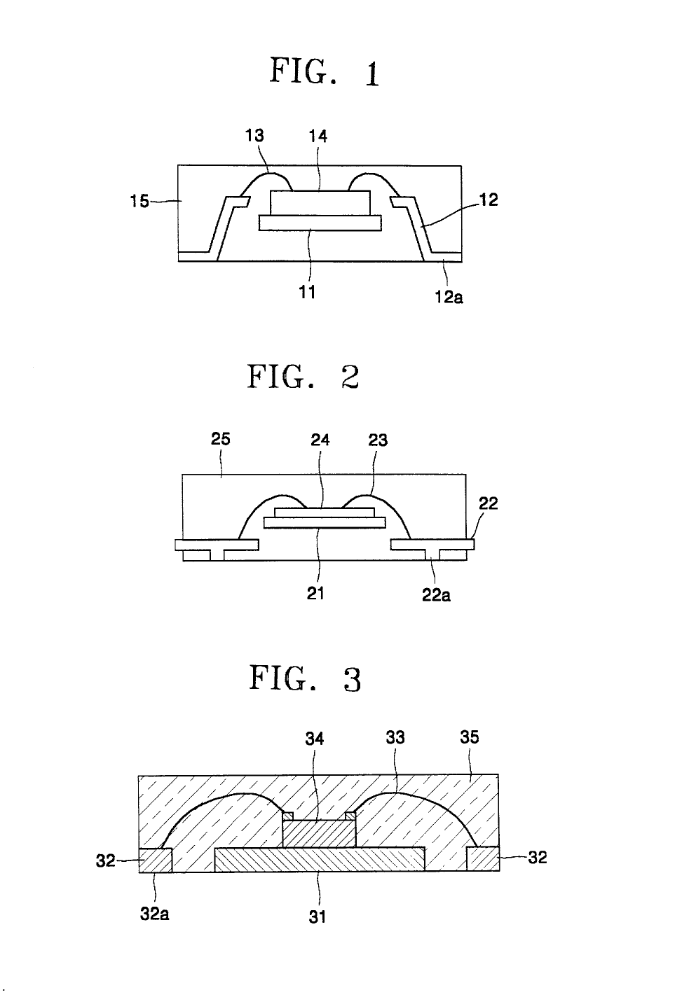

### DETAILED DESCRIPTION OF THE INVENTION

Reference will now be made in detail to exemplary embodiments consistent with the invention, examples of which are illustrated in the accompanying drawings. Wherever possible, the same reference numbers will be used throughout the drawings to refer to the same or like parts.

Referring to FIG. 7, in a semiconductor package according to an embodiment consistent with the present invention, a semiconductor chip 74 is attached to the bottom surface of a pad 71. A lead 72 is arranged at a height different from the pad 71. The pad 71 and the lead 72 can receive a predetermined process by half-etching and are plated with noble metal such as silver or palladium. The lead 72 and the semiconductor chip 74 are connected by a bonding wire 75. The pad 71, the lead 72, and the semiconductor chip 74 are encompassed by an encapsulation 76. A tie bar which is not shown in the drawing has one end connected to the edge of the pad 71 and extending therefrom and the other end thereof extending to the same height as the lead 72. The tie bar is down-set processed and will be described in detail later.

In the semiconductor package as shown in FIG. 7, the upper surface of the pad 71 is exposed to the upper surface of the encapsulation 76 and the bottom surface of the lead 72 is exposed to the bottom surface of the encapsulation 76. The bottom surface of the exposed lead 72 contacts a connection terminal of a printed circuit board to form an electrical connection circuit. The upper surface of the exposed pad 71 may help dissipate the heat generated from the semiconductor chip 74 to the outside.

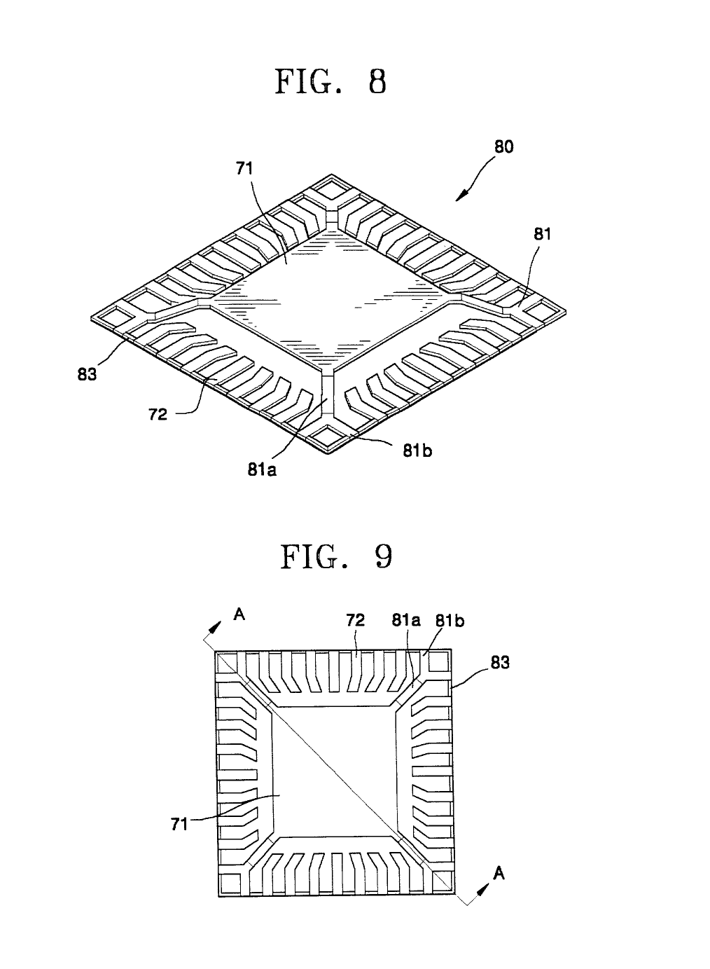

FIG. 8 shows a lead frame used in the semiconductor package shown in FIG. 7. FIG. 9 is a plan view of the lead frame of FIG. 8. Referring to the drawings, a tie bar 81 extends from the edge of the pad 71 and a plurality of the leads 72 are arranged around the pad 71. As described above, the pad 71 and the lead 72 are arranged at different axial planes. This is because the tie bar 81 supports the pad 71 at a higher plane than the plane of the lead 72. That is, as a particular portion of the tie bar 81 is down-set processed, the pad 71 may be maintained at a different axial plane with respect to the plane of the lead 72. Reference numeral 81a denotes a portion of the tie bar 81 which is down-set processed. Reference numeral 81b denotes a connection portion of the tie bar 81 connected to the lead 72 and supporting the pad 71 at a different axial plane. The connection portion 81b and the lead 72 are arranged on the same axial plane. The tie bar 81 and the lead 72 are connected via a support portion 83.

A plurality of the above-described lead frames shown in FIGS. 8 and 9 are connected in a matrix format, thus forming a lead frame unit as shown in FIG. 5. Actually, prior to performing a down-set process, the pad 71, the lead 72 and the tie bar 81 are formed by means of punching, etching or stamping. The down-set process is performed by a mold such that the tie bar 81 supports the pad 71 as shown in FIG. 8. The support portion 83 connecting the lead 72 can be removed usually after molding is performed.

Hereinafter, a method of manufacturing a semiconductor package consistent with the present invention will now be described.

A lead frame used in a semiconductor package consistent with the present invention may be manufactured in a typical method. That is, the pad, lead, and tie bar are formed by etching or stamping, and at least an inner lead portion or a pad portion to be wire-bonded is plated with silver or palladium. The thickness and type of plating differs based on the purpose of a product. Recently, PPF plating using a nickel/palladium material is primarily applied. After the lead frame is manufactured, a down-set process is performed in a mechanical manner. That is, as shown in FIG. 8, the tie bar 81 is plastically deformed so that the tie bar 81 supports the lead portion and the pad 71 at different planes.

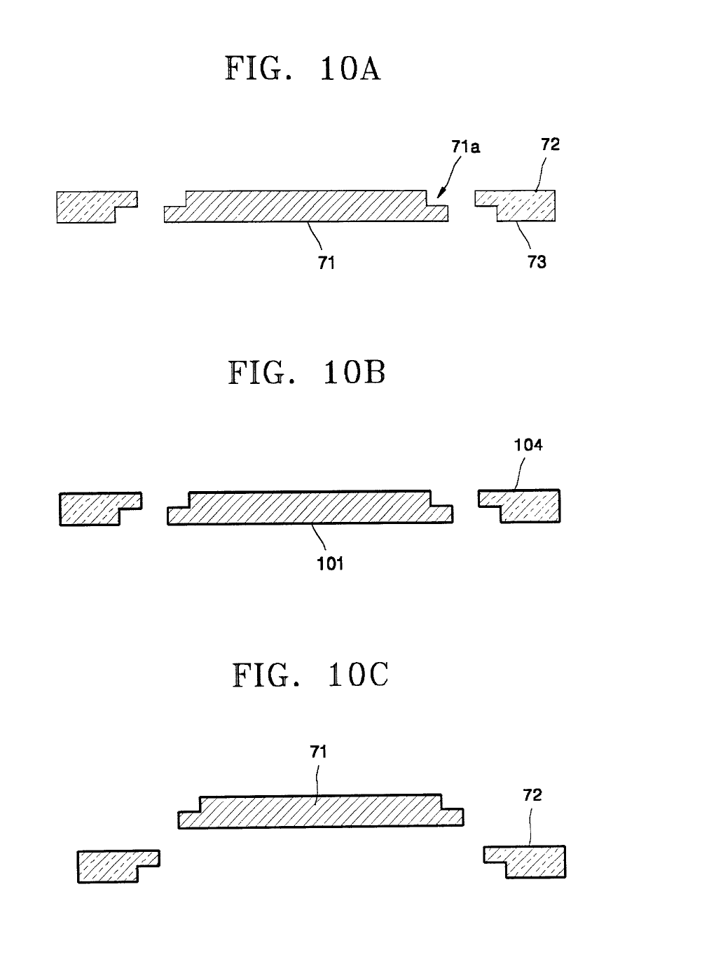

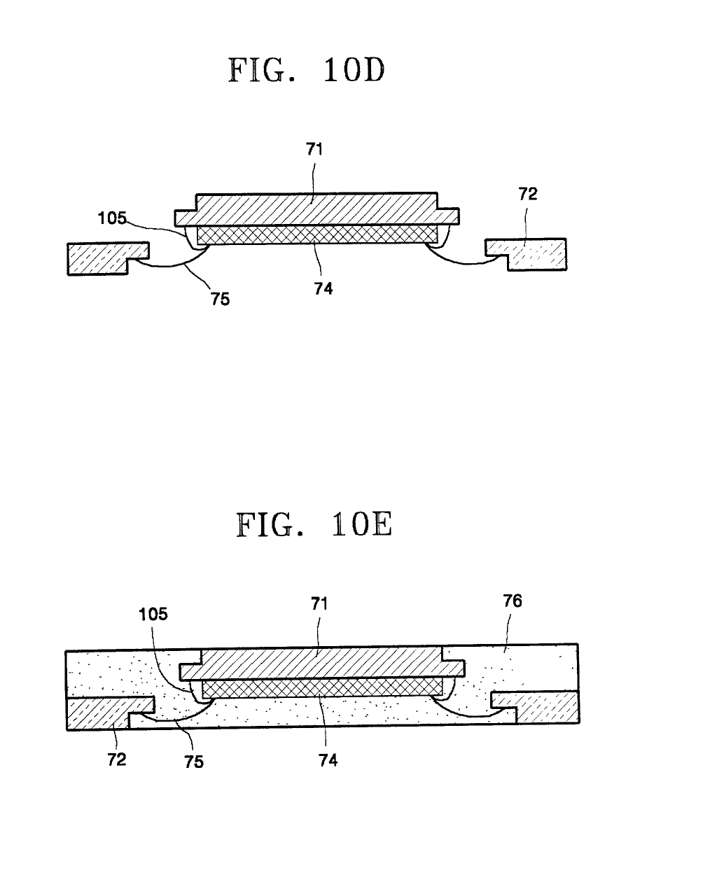

FIGS. 10A through 10E show a method of manufacturing a chip scale package consistent with the present invention. Referring to FIG. 10A, a material for a lead frame is half-etched to have a predetermined section. A land 73 is formed at the lead 72 through half-etching. The land 73 is a portion exposed to the bottom surface of the encapsulation 75 of a package. Also, the pad 71 is half-etched along an edge side 71 a thereof, so that adhesion between the encapsulation resin and the pad 71 which are molded later is improved.

As described in FIG. 9, the pad 71 is connected to the lead 72 via the tie bar 81 and the support portion 83 in a state in which the half-etching process has been performed.

Referring to FIG. 10B, plate layers 101 and 104 are formed on the surfaces of the pad 71 and the lead 72, respectively. Plating is performed with nickel, palladium, or silver.

Referring to FIG. 10C, the lead 72 is down-set processed. The same result may be obtained if the pad 71 is up-set processed. That is, the down-set portion 81a of the tie bar 81 is bent by using a mold, as shown in FIG. 9. Thus, the pad 71 and the lead 72 are positioned at different axial planes through the down-set or up-set process.

Referring to FIG. 10D, the semiconductor chip 74 is attached to the bottom surface of the pad 71, and a wire-bonding step to connect the electrode of the semiconductor chip 74 and the lead 72 by a bonding wire 75 is performed. A ground wire 105 is directly connected to the pad 71 so as to be electrically connected to the connection portion 81b serving as a ground terminal via the tie bar as described above.

Referring to FIG. 10E, the encapsulation 76 is formed by molding the semiconductor chip 74, the pad 71, and the bonding wire 75. The land 73 of the lead 72 is molded to be exposed to the bottom surface of the encapsulation 76, as described above. The upper surface of the pad 71 may be formed near the surface of or exposed outside the encapsulation 76. Although not shown in the drawing, a heat sink is attached to the upper surface of the pad 71, so that the heat generated from the semiconductor chip 74 can be effectively dissipated.

FIG. 11 shows the bottom surface of the semiconductor package manufactured as described above. Referring to the drawing, a plurality of the leads 72 are arranged around the bottom surface of the package which is rectangular. The connection portions 81b of the tie bar functioning as the ground terminal are arranged at the four corners. As described above, the connection portions 81b are connected to the pad 71 via the tie bar 81 which is not trimmed so that a predetermined ground function can be performed.

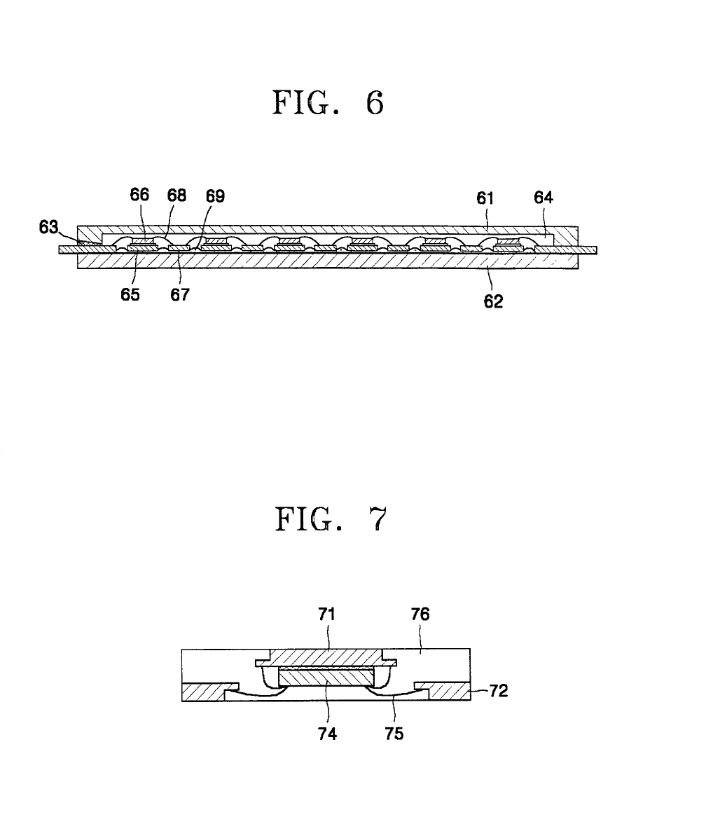

The down-set method with respect to the tie bar 81 has an important meaning when molding is performed and is one of various features of the present invention. As described in the above with reference to FIG. 6, the space for accommodating the lead frame where the semiconductor chip is mounted is formed inside the molding plate. When the thickness of the space in the molding plate is and the entire height of the lead frame unit after the down-set process is performed is t2, the down-set process is performed such that t1<t2. That is, the entire height of the lead frame unit after the down-set process is performed must be formed to be greater than the thickness of the space in the molding plate. Thus, while molding is performed in the state in which the upper and lower plates of the molding plate are clamped each other, the upper surface of the pad 71 of FIG. 8 is pressed against the inner surface of the upper plate and the bottom surface of the connection portion 81b of the tie bar 81 is pressed against the inner surface of the lower plate. Also, the bottom surface of the lead 72 connected to the connection portion 81b of the tie bar 81 via the support portion 83 is pressed against the inner surface of the lower plate.

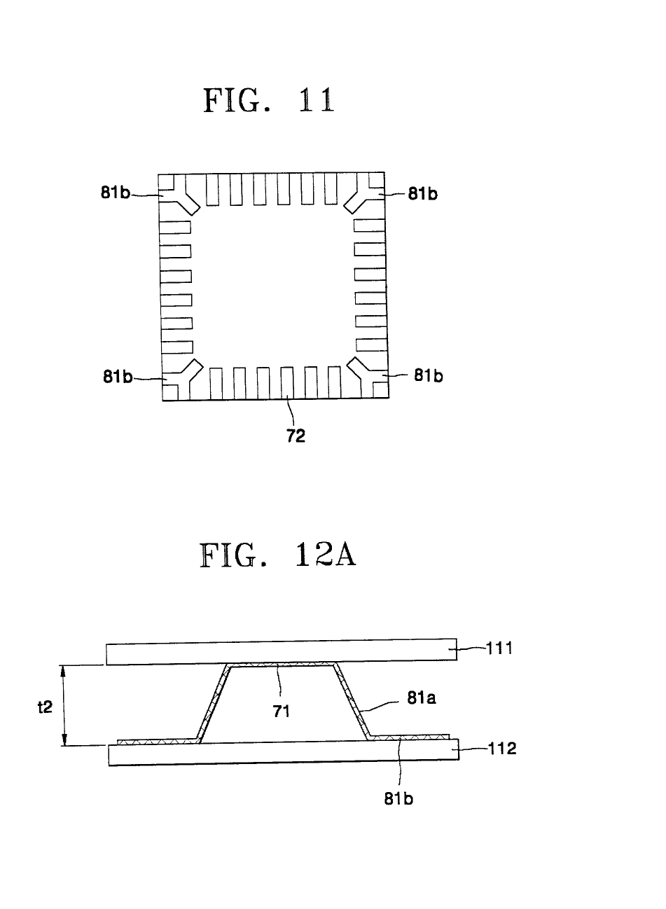

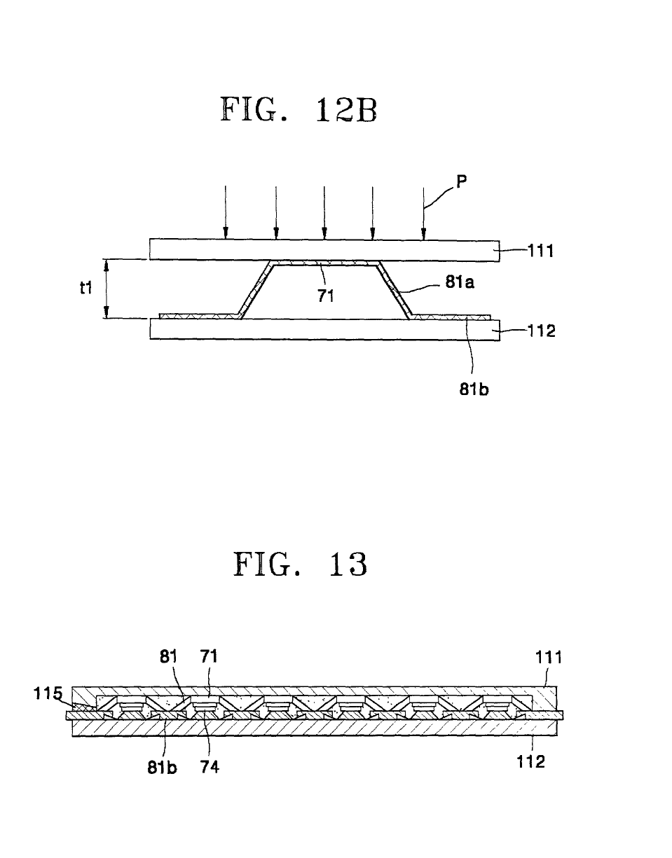

FIGS. 12A and 12B show a state in which the lead frame is pressed by the molding plate. In the drawings, the lead frames have sections which are taken along line A-A of FIG. 9. In FIG. 12A, when an upper plate 111 and a lower plate 112 are not pressed by a clamp (not shown), the entire height of a down-set processed lead frame is t2.

The lead frame is disposed between the upper and lower plates 111 and 112 and receives clamping pressure P as shown in FIG. 12B. The depth of the space between the upper and lower plates 111 and 112 becomes t1 as shown in FIG. 12B because the lead frame is elastically deformed. Thus, the upper surface of the pad 71 and the connection portion 81b of the tie bar 81 are supported by being pressed against the inner surface of the upper plate 111 and the inner surface of the lower plate 112, respectively. Also, the bottom surface of the lead 72 connected to the tie bar 81 via the support portion 83 is supported by being pressed by the inner surface of the lower plate 112. In this state, when resin molding is performed, resin flows between the lead 72 and the lower plate 112 and between the pad 71 and the upper plate 111, so that a flash phenomenon is prevented.

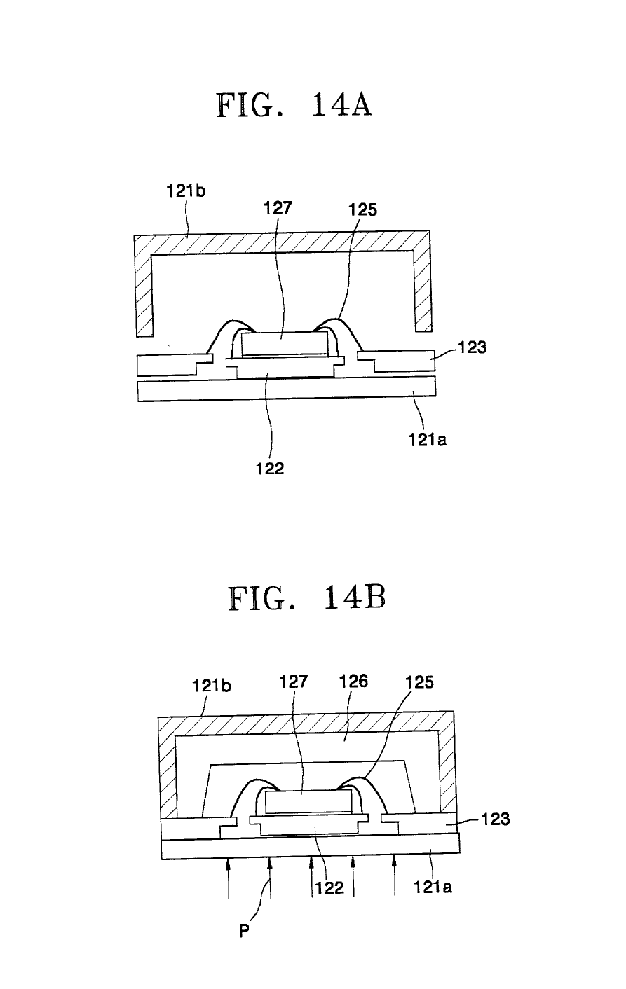

FIG. 13 shows a molding process, in which a matrix type lead frame unit on which semiconductor chips are mounted is accommodated in the molding plate. Referring to the drawing, a lead frame on which the semiconductor chips 74 are mounted is accommodated in the space inside the molding plate including the upper and lower plates 111 and 112. The pad 71 of the lead frame contacts the inner surface of the lower plate 112 with pressure. Molding resin is injected through a gate 115 of the molding plate and molding is performed. After the molding is performed, flash is removed, marking is performed, and dam bar is removed in a typical manner. Finally, the molding resin is severed so that individual semiconductor packages are obtained.

FIGS. 14A and 14B shows a method of manufacturing a semiconductor package according to another embodiment consistent with the present invention. In the semiconductor package, both the lead and the pad are exposed to the bottom surface of the semiconductor package. Consequently, the semiconductor package has a cross section similar to that of the semiconductor package shown in FIG. 3.

Referring to FIG. 14A, molding plates 121a and 121b are not pressed and, in such a state, a pad 122 on which a semiconductor chip 127 is mounted is down-set processed at a position lower than a lead 123. That is, when the lead frame is down-set processed, the height of the pad 122 is set to be lower than that of the lead 123. Reference numeral 125 denotes a bonding wire.

FIG. 14B shows a state in which molding resin 126 is injected when the molding plates 121a and 121b are clamped. The lead frame accommodated between the molding plates 121a and 121b receives a clamping pressure indicated by P. When the molding plate is clamped, the pad 122 contacts the inner surface of the lower plate 121a with pressure, so that a flash phenomenon can be prevented.

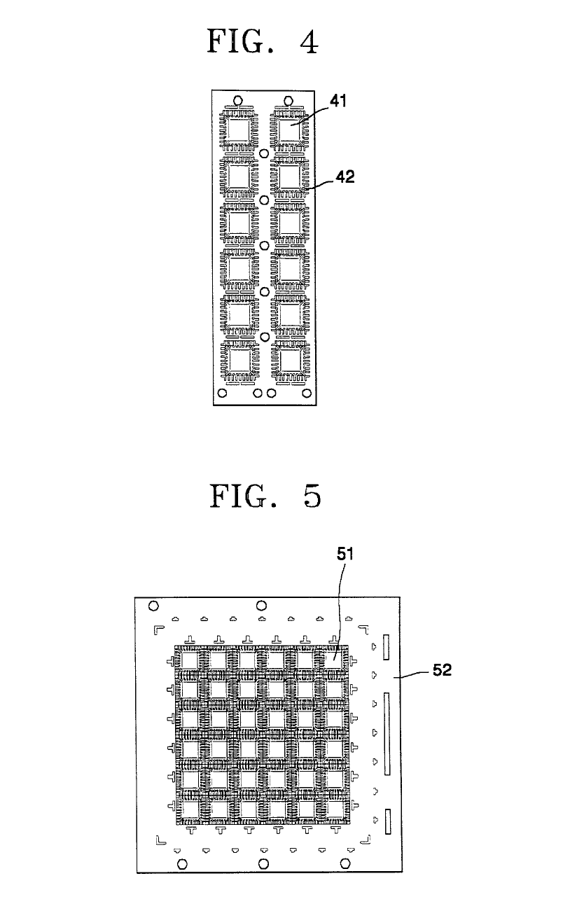

Actually, the method for manufacturing a semiconductor package described with reference to FIGS. 14A and 14B is preferably applied to the case in which the lead frame is individually molded. That is, it is preferable to perform the method shown in FIGS. 14A and 14B for the lead frame unit shown in FIG. 4, rather than for the matrix type lead frame unit shown in FIG. 5. However, the lead frame unit shown in FIG. 5 is more preferable than that shown in FIG. 4 in view of manufacturing cost and process.

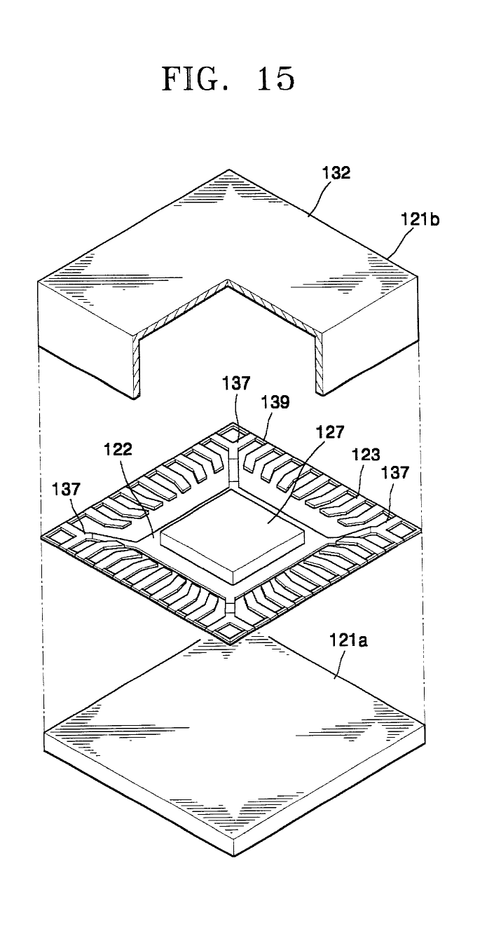

FIG. 15 shows the method of manufacturing a semiconductor package described with reference to FIGS. 14A and 14B. Referring to the drawing, a tie bar 137 extends from a pad 122 on which a semiconductor chip 127 is mounted. The tie bar 137 and the lead 123 are connected by a support portion 139. The support portion 139 and the lead 123 are disposed on the same plane and the pad 122 is down-set processed at an axial plane different from a plane of the support portion 139 and the lead 123. Here, a bonding wire is not shown for the convenience of illustration. When the upper plate 121b of the molding plate covers over the lower plate 121a, an outer portion 132 of the upper plate 121b for forming an inner space clamps the lead 123 and the support portion 139. Here, since the pad 122 is down-set processed at a position lower than the plane of the lead 123 and the support portion 139, when the lead 123 and the support portion 139 are clamped, the bottom surface of the pad 122 contacts the upper surface of the lower plate 121a with pressure. Thus, when molding resin is injected into the space formed inside the molding plate, possibility of flash generation between the bottom surface of the pad 122 and the upper surface of the lower plate 121a is prevented.

As described above, in the lead frame consistent with the present invention, since the pad and the tie bar extending from the pad are down-set or up-set processed to be placed on different planes, a flash phenomenon that can be generated in the molding plate during the encapsulation step is prevented. Thus, the semiconductor package manufacturing method incorporating a matrix type lead frame unit can be utilized without adverse effects caused by the flash phenomenon. Also, reliability in manufacture of semiconductor packages is improved. Furthermore, high productivity at a lower manufacturing cost can be expected.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A lead frame for an encapsulated semiconductor package having a predetermined thickness, comprising:
a pad for receiving a semiconductor chip, the pad having a top surface;
a support portion having a bottom surface and a plurality of leads formed on the support portion;
a resilient tie bar having a first end connected to the pad and a second end connected to the support portion, the tie bar when in an unstressed condition supporting the pad such that the top surface of the pad and the bottom surface of the supporting portion and leads are separated by a distance greater than the predetermined thickness.

2. The lead frame as claimed in claim 1, wherein the tie bar is down-set processed.

3. The lead frame as claimed in claim 1, wherein at least a portion of the plurality of leads is half-etched.

4. The lead frame as claimed in claim 3, wherein the half-etched portion is electrically connected to the semiconductor chip.

5. The lead frame as claimed in claim 1, wherein the lead frame when in a stressed condition is configured to fit into a space defined by a pair of molding plates separated by a distance of the predetermined thickness.

6. An encapsulated semiconductor package having a predetermined thickness, comprising:
a pad having a first surface and a second surface opposite to the first surface;
a support portion having a bottom surface and a plurality of leads formed on the support portion;
a semiconductor chip attached to the first surface of the pad;
a resilient tie bar having a first end connected to the pad and a second end connected to the support portion; and
an encapsulation having a first surface and a second surface opposite to the first surface;
the second surface of the pad being exposed to the first surface of the encapsulation and the leads being exposed to the second surface of the encapsulation.

7. The encapsulated semiconductor package as claimed in claim 6, wherein the second surface of the pad and the bottom surface of the support portion are separated by a predetermined distance.

8. The encapsulated semiconductor package as claimed in claim 7, wherein the predetermined distance prior to forming the encapsulation is greater than the predetermined thickness.

9. The encapsulated semiconductor package as claimed in claim 6, comprising at least one bonding wire connected between an electrode of the semiconductor chip and each of the plurality of leads.

10. The encapsulated semiconductor package as claimed in claim 6, wherein the resilient tie bar is down-set processed.

11. The encapsulated semiconductor package as claimed in claim 6, wherein the pad and the support portion when in a stressed condition are configured to fit into a space defined by a pair of molding plates separated by a distance of the predetermined thickness.

12. The encapsulated semiconductor package as claimed in claim 6, wherein:
the first surface of the pad is the bottom surface of the pad and the second surface of the pad is the upper surface of the pad; and
the first surface of the encapsulation is the upper surface of the encapsulation and the second surface of the encapsulation is the bottom surface of the encapsulation.

13. The encapsulated semiconductor package as claimed in claim 6, wherein:
the first surface of the pad is the upper surface of the pad and the second surface of the pad is the bottom surface of the pad; and
the first surface of the encapsulation is the bottom surface of the encapsulation and the second surface of the encapsulation is the upper surface of the encapsulation.

14. The encapsulated semiconductor package as claimed in claim 6, wherein at least a portion of the plurality of leads is half-etched.

15. The encapsulated semiconductor package as claimed in claim 14, wherein the half-etched portion is electrically connected to the semiconductor chip.

16. A method of manufacturing a semiconductor package, comprising: providing a lead frame comprising:
a pad,
a plurality of leads, and a tie bar extending from the pad and supporting the pad;
down-set processing the tie bar so that the pad and the leads are disposed on different axial planes with a predetermined distance from each other;
deforming the lead frame by providing a pair of molding plates on opposite sides of the lead frame and separated from each other by a predetermined thickness for forming an encapsulation, the predetermined thickness being less than a sum of the predetermined distance, a thickness of the pad, a thickness of the lead; and
injecting a molding resin between the molding plates to form an encapsulated package.

17. The method as claimed in claim 16, comprising a step of half-etching at least a portion of the leads.

18. The method as claimed in claim 17, comprising a step of electrically connecting the half-etched portion to a semiconductor chip.

19. The method as claimed in claim 16, comprising attaching a semiconductor chip to one surface of the pad.

20. The method as claimed in claim 19, comprising connecting an electrode of the semiconductor chip and the leads by a bonding wire.

21. The method as claimed in claim 19, comprising:
accommodating the lead frame in the inside space between the pair of molding plates, pressing the pad which makes a contact with a surface of one of the molding plates; and
injecting the molding resin into the inside space while pressing the pad, thus forming the encapsulation.

22. The method as claimed in claim 21, comprising cutting a portion connecting to the leads.

23. The method as claimed in claim 19, wherein the semiconductor chip is attached to a bottom surface of the pad.

24. The method as claimed in claim 19, wherein the semiconductor chip is attached to the upper surface of the pad.

25. The method as claimed in claim 16, wherein the lead frame is provided as a lead frame unit where a plurality of lead frames are connected in a matrix format.

26. The method as claimed in claim 16, wherein the lead frame is an individually molded and trimmed lead frame.

27. The method as claimed in claim 16, wherein the plurality of leads are formed on a support portion, the support portion connected to the tie bar for providing a support for the pad.
